(19) United States
(12) Patent Application Publication
(10) Pub. No.: US 2025/0079211 A1
(43) Pub. Date: Mar. 6, 2025

(54) ANOMALY DETECTION METHOD AND SEMICONDUCTOR DEVICE MANUFACTURING METHOD INCLUDING THE SAME

(71) Applicant: SAMSUNG ELECTRONICS CO., LTD., Suwon-si (KR)

(72) Inventors: Sewoong Lee, Suwon-si (KR); Jaeho Jang, Suwon-si (KR); Yohwan Joo, Suwon-si (KR); Jinkyou Choi, Suwon-si (KR)

(21) Appl. No.: 18/653,168

(22) Filed: May 2, 2024

(30) Foreign Application Priority Data
Aug. 28, 2023 (KR) 10 2023 0113176

(51) Int. Cl. H01L 21/67; G06N 3/045

(52) U.S. Cl. CPC H01L 21/67288; G06N 3/045; H01L 21/67253

(57) ABSTRACT

An anomaly detection method includes receiving data regarding semiconductor process variables, generating an anomaly detection model through a convolution algorithm and a transformer algorithm, classifying the data by using the generated anomaly detection model, and detecting, based upon the classified data, an anomaly associated with the semiconductor process variables.

### CROSS-REFERENCE TO RELATED APPLICATION

This application claims priority to Korean Patent Application No. 10-2023-0113176, filed in the Korean Intellectual Property Office on Aug. 28, 2023, the disclosure of which is incorporated by reference herein in its entirety.

### BACKGROUND

A neural network refers to a computational architecture that models the brains of animals. As neural network technology has been developed lately, research is being actively conducted in various fields to analyze input data received from the outside and extract valid information using a neural network device. Also, semiconductor devices are becoming more integrated and semiconductor processes are becoming more diverse. Accordingly, new types of anomalies occur more frequently in the semiconductor process, and research is being continuously conductive to detect new types of anomalies using a neural network.

### SUMMARY

In general, in some aspects, the present disclosure is directed toward an anomaly detection method and a semiconductor device manufacturing method to perform reliable anomaly detection for a semiconductor process.

According to some aspects of the present disclosure, an anomaly detection method includes receiving data regarding semiconductor process variables, generating an anomaly detection model through a convolution algorithm and a transformer algorithm, classifying the data by using the generated anomaly detection model, and detecting, based upon the classified data, an anomaly associated with the semiconductor process variables.

According to some aspects of the present disclosure, an anomaly detection method includes receiving time-series data regarding semiconductor process parameters, generating an anomaly detection model, classifying the time-series data using the generated anomaly detection model, and detecting, based upon the classified data, an anomaly associated with the semiconductor process parameters, wherein the generating of the anomaly detection model includes performing pre-processing on the time-series data, generating the anomaly detection model through a convolution algorithm and a transformer algorithm, calculating a loss function of the anomaly detection model, and calibrating the anomaly detection model.

According to some aspects of the preset disclosure, an anomaly detection method includes receiving, using at least one computing device, time-series data representing semiconductor process parameters, generating, using the at least one computing device, an anomaly detection model, classifying, using the at least one computing device, the time-series data using the anomaly detection model to produce classified time-series data and detecting, using the at least one computing device, based upon the classified time-series data, an anomaly associated with the semiconductor process parameters, wherein generating the anomaly detection model includes performing pre-processing on the time-series data, generating the anomaly detection model, calculating a loss function of the anomaly detectin model and calibrating the anomaly detection model, wherein generating the anomaly detectin model includes performing a time convolution algorithm on the time-series data and performing a transformer decoder algorithm on the time-series data.

### BRIEF DESCRIPTION OF THE DRAWINGS

Exemplary implementations will be more clearly understood from the following description, taken in conjunction with the accompanying drawings.

FIG. 1 is a block diagram showing an example of a semiconductor device manufacturing apparatus according to some implementations.

FIG. 2 is a schematic diagram showing an example of a semiconductor process system according to some implementations.

FIG. 3 is a flowchart of an example of an anomaly detection method using an anomaly detection system according to some implementations.

FIG. 4 is a diagram showing an example of a process of an anomaly detection method according to some implementations.

FIG. 5 is a flowchart of an example of a method for generating an anomaly detection model according to some implementations.

FIG. 6 is a schematic diagram for describing an example of a temporal convolution network according to some implementations.

FIG. 7 is a diagram showing an example of a transformer decoder algorithm according to some implementations.

FIG. 8 is a flowchart of an example of a semiconductor device manufacturing method using an anomaly detection method according to some implementations.

FIG. 9 is a block diagram showing an example of a semiconductor device manufacturing apparatus according to some implementations.

### DETAILED DESCRIPTION

Hereinafter, exemplary implementations will be described in detail with reference to the accompanying drawings. The same reference numerals are used for the same elements in the drawings, and repeated descriptions thereof are omitted.

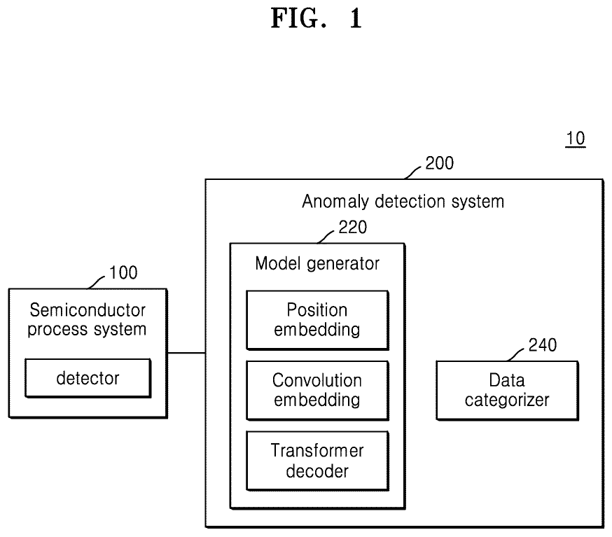

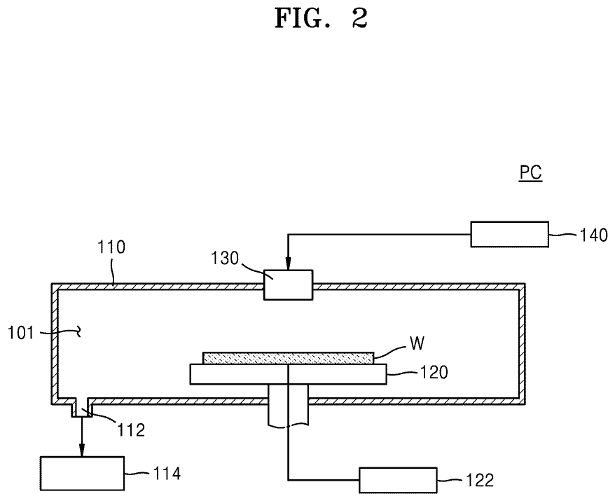

FIG. 1 is a block diagram showing an example of a semiconductor device manufacturing apparatus according to some implementations. In FIG. 1, a semiconductor device manufacturing apparatus 10 may include a semiconductor process system 100 and an anomaly detection system 200. The semiconductor device manufacturing apparatus 10 may perform a semiconductor process on a wafer W (in FIG. 2) through the semiconductor process system 100 and then determine whether there is an anomaly in the semiconductor process through the anomaly detection system 200.

In some implementations, the semiconductor process system 100 may perform various processes on the wafer W (in FIG. 2). For example, the semiconductor process system 100 may perform an oxidation process, a photo process, a deposition process, an etching process, an ion process, and/or a cleaning process on the wafer W (in FIG. 2).

The semiconductor process system 100 may detect variables of a semiconductor process, such that the anomaly detection system 200 determines whether the semiconductor process performed by the semiconductor process system 100 is abnormal. In some implementations, the semiconductor process system 100 may include a detector that detects process variables. For example, the semiconductor process system 100 may sense a flow rate of a gas, a current, a voltage, a pressure, and/or an amount of light inside a semiconductor process chamber. Process variables detected by the semiconductor process system 100 are not limited thereto, and any variable used to determine whether a semiconductor process is abnormal may be detected by the semiconductor process system 100. Here, sensed process variables may include time-series data. An example of the semiconductor process system 100 is described in detail with reference to FIG. 2.

The anomaly detection system 200 may determine whether there is an anomaly in the semiconductor process performed on the wafer W (in FIG. 2) based on process variables detected by the semiconductor process system 100. Based upon the anomaly detection system 200 determining that there is an anomaly in the semiconductor process performed on the wafer W, one or more of the process variables may be adjusted to mitigate (or prevent) issues in the semiconductor process performed on the wafer W. The anomaly detection system 200 may include a model generator 220 that generates an anomaly detection model regarding time-series data and a data classifier 240 that determines whether the time-series data is abnormal through the anomaly detection model.

As will be described below, the anomaly detection system 200 may determine whether there is an anomaly in a semiconductor process performed on the wafer W (in FIG. 2) based on a convolution algorithm and a transformer decoder algorithm. For example, model generator 220 may include positional embeddings, 1-dimensional convolutional embeddings, and/or transformer decoders. The process by which the anomaly detection system 200 determines whether there is an anomaly in the semiconductor process will be described in detail with reference to FIGS. 2 to 7.

FIG. 2 is a schematic diagram showing an example of a semiconductor process system according to some implementations. Descriptions below will be given with reference to FIGS. 1 and 2, together. In FIG. 2, a case in which the semiconductor process system 100 includes a deposition apparatus will be described as an example. In FIG. 2, the deposition apparatus may include a process chamber PC, a housing 110, an exhaust port 112, a vacuum pump 114, a wafer support unit 120, a heating unit 122, a supply port 130, and a gas source 140. The deposition apparatus may perform a thin-film formation process using chemical adsorption and desorption by saturated surface reaction of a reaction material on the wafer W.

The process chamber PC may be a single wafer type and includes the housing 110 that forms an internal region 101 of the process chamber PC. The housing 110 may be manufactured from a single aluminum block. The housing 110 may include a conduit, and a fluid for controlling the temperature of the housing 110 may flow through the conduit. Also, the process chamber PC may include the exhaust port 112 connecting the internal region 101 of the process chamber PC to the vacuum pump 114.

The wafer support unit 120 may be disposed nearby the center of the internal region 101 of the process chamber PC. The wafer support unit 120 may fix and support the wafer W during a process of inducing adsorption of a material film. According to some implementations, the wafer support unit 120 may be made of aluminum, ceramic, or a combination of aluminum and ceramic and may include a vacuum unit and the heating unit 122.

The wafer support unit 120 may fix the wafer W by applying a vacuum between the wafer W and the wafer support unit 120 using the vacuum unit. The heating unit 122 may heat the wafer W disposed on the wafer support unit 120 to a certain temperature.

The supply port 130 may be disposed near the top of the housing 110. The supply port 130 may be connected to the gas source 140. A gas flow is supplied to the internal region 101 of the process chamber PC through a shower head 132.

The semiconductor device manufacturing apparatus 10 may determine whether there is an anomaly in a semiconductor deposition process by sensing a flow rate of a gas supplied into the internal region 101 of the process chamber PC, a flow rate of a gas exhausted from the internal region 101 of the process chamber PC to the outside of the process chamber PC, and a temperature, a pressure, and/or a current inside the internal region 101 of the process chamber PC. The semiconductor device manufacturing apparatus 10 may obtain time-series data and determine whether there is an anomaly in a semiconductor process. However, the semiconductor process system 100 included in the semiconductor device manufacturing apparatus 10 is not limited to a deposition apparatus and may include apparatuses that perform an oxidation process, a photo process, an etching process, an ion process, and/or a cleaning process.

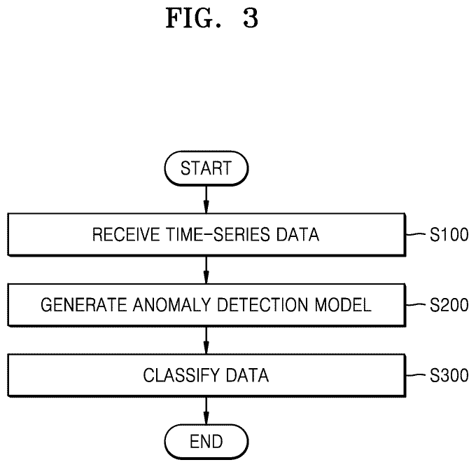

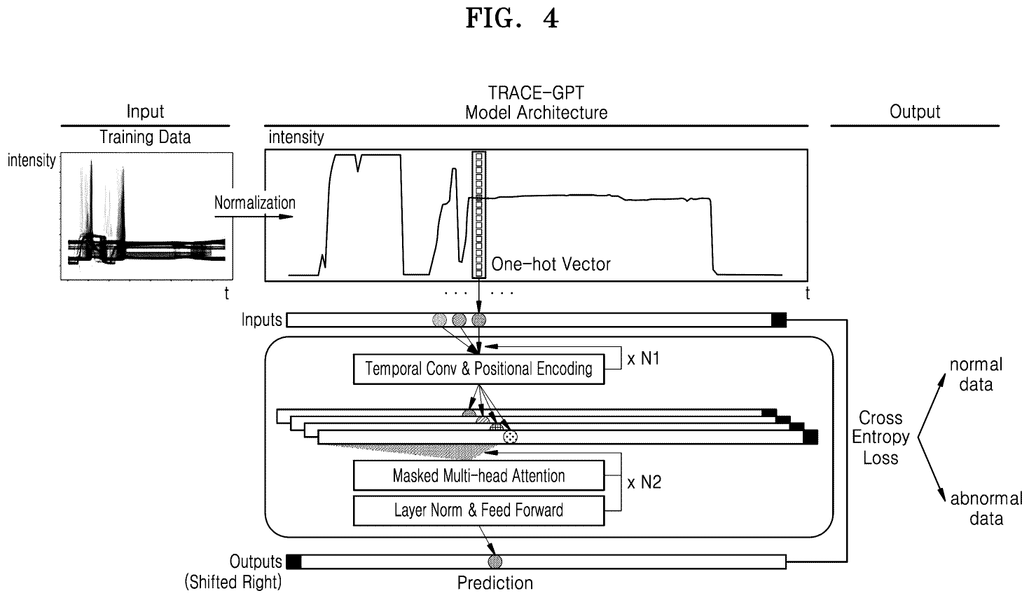

FIG. 3 is a flowchart of an example of an anomaly detection method using an anomaly detection system according to some implementations, and FIG. 4 is a diagram showing the process of an anomaly detection method according to some implementations. Descriptions below will be given with reference to FIGS. 3 and 4, together. In FIGS. 3 and 4, first, time-series data may be received (operation S100). The time-series data may be measured by the semiconductor process system 100 and input into the anomaly detection system 200. For example, the semiconductor process system 100 and the anomaly detection system 200 may be connected through a network and data may be transmitted to each other.

As described above, the time-series data may include the flow rate of a gas supplied to the internal region 101 of the process chamber PC, the flow rate of a gas exhausted from the internal region 101 of the process chamber PC to the outside of the process chamber PC, and a temperature, a pressure, and/or a current of the internal region 101 of the process chamber PC. However, the time-series data is not limited to the above-stated examples and may include any data based on which an anomaly of a semiconductor process may be determined. For example, time-series data may include data of a single category and/or may include a combination of data of a plurality of categories.

Thereafter, at least one piece of received time-series data may be classified as training time-series data. Time-series data that is not training time-series data may be time-series data (evaluation time-series data) that will later be classified as normal data or abnormal data. The training time-series data may include unlabeled data that is not classified as normal data or abnormal data. Accordingly, the anomaly detection method may train a model through unsupervised learning method.

In FIG. 4, an example of the training time-series data is shown in an input region. The training time-series data is shown in the form of a graph, where the horizontal axis represents time, and the vertical axis represents the intensity of process data (e.g., the flow rate of a process gas, a pressure inside a chamber, etc.). Both the horizontal axis and the vertical axis are shown in arbitrary units (a.u.).

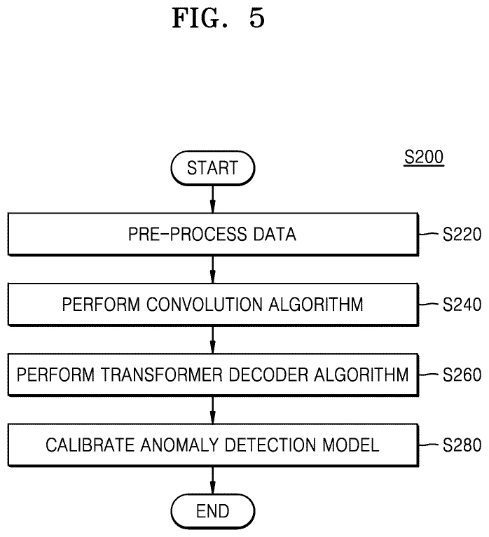

Thereafter, an anomaly detection model may be generated through the training time-series data (operation S200). Through the anomaly detection model, it may be determined whether input time-series data is abnormal (i.e., whether a process is abnormal). The anomaly detection model may include a convolution algorithm and/or a transformer decoder algorithm. The method of generating an anomaly detection model will be described in detail below with reference to FIG. 5.

FIG. 5 is a flowchart of an example of a method for generating an anomaly detection model according to some implementations. Descriptions below will be given with reference to FIGS. 1 to 4, together.

In FIG. 5, first, pre-processing is performed on the training time-series data (operation S220). The pre-processing in operation S220 may include performing normalization, noise removal, and/or positional encoding on the training time-series data. The normalization refers to scaling data to train an algorithm.

The positional encoding may refer to providing order information and/or positional information regarding data to a model. For example, positional encoding for the training time-series data may be performed using the sine function and/or cosine function, which are trigonometric functions. Alternatively, positional encoding may be performed based on the dimension (or the length) of the time-series data. However, in some implementations, the positional encoding are not limited thereto, and the positional encoding may be performed in various ways. According to some implementations, positional encoding may be omitted.

FIG. 4 shows an example in which training time-series data in an input region is normalized to form a normalized graph. In the normalized graph, the horizontal axis represents time, and the vertical axis represents the intensity of normalized process data (e.g., the flow rate of a process gas, a pressure inside a chamber, etc.). Both the horizontal axis and the vertical axis are shown in arbitrary units (a.u.).

The anomaly detection model according to some implementations, which detects an anomaly by applying a convolution algorithm and a transformer decoder (GPT) algorithm to time-series data, may be referred to as a Time-Series, and Anomaly detection with Convolutional Encoding and Generative Pre-Training (TRACE-GPT) model.

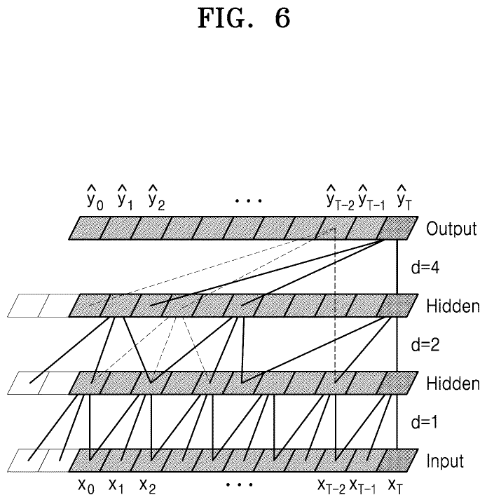

Thereafter, a convolution algorithm may be performed on pre-processed training time-series data (operation S240). For example, a temporal convolution algorithm may be performed on the pre-processed training time-series data. The temporal convolution algorithm is a convolution algorithm that uses the causal convolution technique and the dilation technique and may refer to a convolution algorithm suitable for sequential data (e.g., the time-series data) having temporality and a large receptive field. A temporal convolution network will be described in detail with reference to FIG. 6.

The dimension of input data may be changed through the convolution algorithm. For example, the convolution algorithm may generate a plurality of output results by changing parameters and/or changing weights. For example, a temporal convolution network may transform the dimension of input data based on the input dimension of a transformer decoder.

As shown in FIG. 4, normalized training time-series data may be input to the temporal convolution algorithm in the form of a one-hot vector that represents the data in a discretized manner. The temporal convolution algorithm may include N1 (N1 is a natural number greater than or equal to 1) layers.

Although FIG. 5 shows that positional encoding for training time-series data is performed prior to performing the temporal convolution algorithm on the training time-series data, according to some implementations, positional encoding for the training time-series data may be performed after performing the temporal convolution algorithm on the training time-series data.

FIG. 6 is a schematic diagram for describing an example of a temporal convolution network according to some implementations. Descriptions below will be given with reference to FIGS. 1 to 5, together. FIG. 6 shows an example of a temporal convolution network including two 1-dimensional convolution layers (hidden layers). Also, in FIG. 6, x0 to xT represent input data, respectively, and ŷ₀ to ŷ_{T} represent output data, respectively. xi denotes input data at a time point i (0≤i≤T), and ŷ_{J} denotes output data at a time point j (0≤j≤T). The input data and the output data are each arranged in time series from t=0 to t=T.

In FIG. 6, the temporal convolution network may include a plurality of 1-dimensional convolution layers, and, as described above, a causal convolution technique and a dilation technique may be used. The temporal convolution network may effectively process time-series data and, in particular, may effectively perform modeling on time-series data.

A temporal convolution network may include a plurality of 1-dimensional convolution layers extending in time series. The plurality of 1-dimensional convolution layers may be stacked to form a temporal convolution network. The plurality of stacked 1-dimensional convolution layers may have the same length. In other words, the length of input sequences, the lengths of the plurality of 1-dimensional convolution layers, and the lengths of output sequences may all be the same. When information is transferred to the plurality of stacked 1-dimensional convolution layers, the causal convolution technique and the dilation technique may be used.

The causal convolution technique may refer to an algorithm in which the output of each time step is convolved only on the past time step and the current time step, not on the future time step. Accordingly, a future value may be predicted based on a past value and a current value through the causal convolution technique. FIG. 6 shows that each 1-dimensional convolution layer receives information only at the past time step and the current time step of a previous convolution layer.

A dilated convolution technique may mean that gaps or dilations are introduced between input data when information is transferred between the pluralities of 1-dimensional convolution layers. Here, a gap or a dilation may refer to a time-series distance between values (e.g., a past value and a current value) received by a hidden layer or an output layer. In FIG. 5, d may refer to a gap and/or a dilated value.

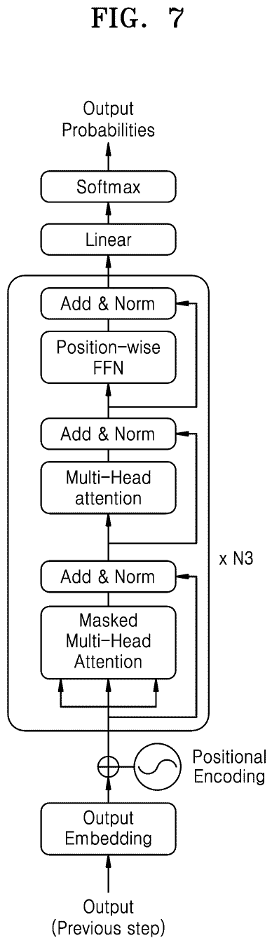

Referring to FIG. 5, the transformer decoder algorithm may be performed on the training time-series data on which the temporal convolution algorithm has been performed (operation S260). By the transformer decoder algorithm, a future value may be predicted based on a past value and a current value. A transformer decoder may include N2 (N2 is a natural number greater than or equal to 1) layers. For example, the transformer decoder may include N2 feed-forward networks (FFN, or Multi-Layer Perceptron: MLP) and multi-head attention. The transformer decoder will be described in detail with reference to FIG. 7.

FIG. 7 is a conceptual diagram showing an example of a transformer decoder algorithm according to some implementations. Descriptions below will be given with reference to FIGS. 1 to 6, together.

In FIG. 7, a transformer decoder may include masked multi-head attention, multi-head attention, layer normalization (also referred to as layer Norm), feed-forward, and linear projection. For example, the transformer decoder may include N3 (N3 is a natural number greater than or equal to 1) masked multi-head attention layers, multi-head attention layers, and feed-forward layers.

First, the transformer decoder may use an output of a previous step as an input. According to some implementations, the output of the convolution algorithm may be input to the transformer decoder. Also, although FIG. 7 shows that positional encoding is performed on the input of the transformer decoder, when an input value is already positionally encoded, the positional encoding may be omitted.

The multi-head attention may include a plurality of self-attentions connected in parallel. A self-attention function may specify information to pay attention to from among input sequences. The self-attention function may calculate the similarity of a given query with respect to all keys and reflect the similarity in respective values mapped to the keys.

The masked multi-head attention may mean that a multi-head attention technique is used by masking a part of input information at each sequence position. Here, masked data means that corresponding data does not belong to the input of an attention function at each location. The masked multi-head attention may mask trailing values at respective positions. For example, when data is input to the transformer decoder in time series (i.e., when past data is input before current data and future data), the masked multi-head attention may only pay attention to preceding data at respective locations and mask trailing data.

The layer normalization may normalize an input. In the transformer decoder algorithm, layer normalization may be performed after masked multi-head attention and/or multi-head attention.

Information paid attention by the self-attention function may be transmitted to the feed-forward. The feed-forward includes a feed-forward network, and a transformed sequence for an input sequence may be output by the feed-forward network. The feed-forward may include a plurality of hidden layers.

The linear projection may transform the form of a transformed sequence generated by the feed-forward. For example, the linear projection may transform the output vector of the feed-forward into a logit vector. The logit vectors may include information regarding the probability of a result. The logit vector formed through the linear projection may be transformed to a probability distribution by a softmax function.

In some implementations, an anomaly detection model may be generated by the convolution algorithm and the transformer decoder algorithm.

Referring to FIG. 5, calibration of the anomaly detection model may be performed (operation S280). To calibrate the anomaly detection model, a loss function may first be calculated. The loss function may indicate the degree of agreement between the predicted values of a model and the actual values of the model. Since the anomaly detection model predicts values through probability distribution, the loss function for the anomaly detection model may be calculated by using cross entropy. In other words, the cross entropy may include information regarding the difference between predicted values of the generated anomaly detection model and the actual values of the generated anomaly detection model. In other words, the larger the cross entropy is, the larger the difference between a predicted value and an actual value may be. FIG. 4 shows calculation of cross entropy by comparing a result value of an anomaly detection model and an input value of the anomaly detection model.

Afterwards, the anomaly detection model may be calibrated through a gradient descent technique and a backpropagation techniques. The backpropagation technique may calculate the gradient of a loss function in the process of adjusting parameters of a model. Backpropagation may transfer information regarding a loss function from an output layer to an input layer (i.e., in the reverse direction), and thus an amount of adjustment of each parameter may be calculated. Here, the amount of adjustment of each parameter may be calculated through the gradient descent technique. The gradient descent technique may be an algorithm used to minimize the loss function of a model. The gradient descent technique may calculate a model that minimizes the loss function by repeatedly adjusting parameters of the model. The gradient descent technique may calculate the gradient of the loss function and adjust the parameters of the model in the direction where the gradient is maximized. For example, the anomaly detection model may be calibrated by the Stochastic Gradient Descent (SGD) algorithm, the Batch Gradient Descent algorithm, the Mini Batch Gradient Descent algorithm, the Adaptive Moment Estimation (Adam) algorithm, the RMSProp algorithm, and/or the Adaptive Gradient (Adagrad) algorithm.

Referring to FIG. 3, data may be classified by the anomaly detection model (operation S300). As described above, time-series data may be classified as normal data or abnormal data by the anomaly detection model generated by the convolution algorithm and the transformer decoder algorithm. The anomaly detection model may calculate a loss function for each time unit of time-series data. When the difference between the cross-entropy of a value predicted by the anomaly detection model and a value of the time-series data is greater than a threshold value, the time-series data may be classified as abnormal. On the contrary, when the difference between the cross-entropy of the value predicted by the anomaly detection model and the value of the time-series data is less than or equal to the threshold value, the time-series data may be classified as normal.

An Output region of FIG. 4 shows that data is classified into normal data and abnormal data based on the cross entropy of values predicted by the anomaly detection model and actual values.

In a general anomaly detection model, whenever a new type of anomaly occurs, the anomaly detection model is updated to determine whether data is abnormal. However, as semiconductor processes become finer and more precise and cases of applying new techniques increase, the frequency of new types of anomalies has increased, and thus additional updates to an anomaly detection model is demanded to detect such anomalies.

The anomaly detection method according to some implementations may be trained in an unsupervised manner by combining a convolution algorithm and a transformer decoder algorithm. Accordingly, various types of anomalies may be detected with high reliability while minimizing updates to the anomaly detection model.

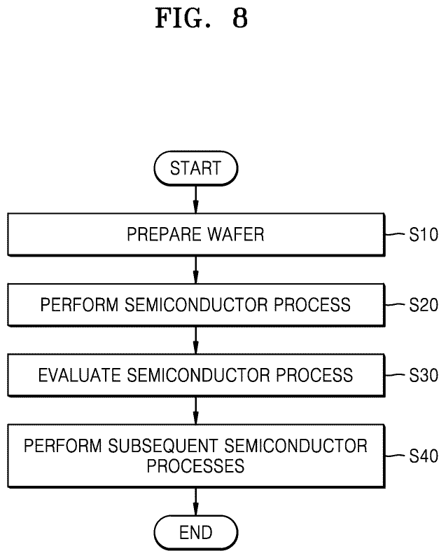

FIG. 8 is a flowchart of an example of semiconductor device manufacturing method using an anomaly detection method according to some implementations. Descriptions below will be given with reference to FIGS. 1 to 7, together.

In FIG. 8, first, the wafer W may be prepared (operation S10). For example, the wafer W may be in a state in which various processes have been performed thereon. For example, an oxidation process, a photo process, a deposition process, an etching process, an ion process, and/or a cleaning process may have been performed on the wafer W.

Then, a semiconductor process may be performed on the wafer W (operation S20). For example, the semiconductor process may include an oxidation process, a photo process, a deposition process, an etching process, an ion process, and/or a cleaning process.

Afterwards, the semiconductor process performed in operation S20 may be evaluated (operation S30). Evaluating the semiconductor process may include evaluating whether the semiconductor process is abnormal. Time-series data may be generated during the semiconductor process. For example, a flow rate of a gas, a current, a voltage, a pressure, a wavelength of light and/or an amount of light, etc. inside a chamber where the semiconductor process is performed may be measured in time series.

The semiconductor process may be evaluated based on the measured time-series data through operation S100 of receiving the time-series data, operation S200 of generating an anomaly detection model, and operation S300 of classifying the time-series data through the generated anomaly detection model. Also, operation S200 of generating the anomaly detection model may include performing pre-processing on training time-series data (operation S220), performing a convolution algorithm on pre-processed training time-series data (operation S240), performing a transformer decoder algorithm on the training time-series data (operation S260), and calibrating the generated anomaly detection model (operation S280). When the semiconductor process is evaluated as being abnormal, equipment conditions and/or process conditions may be changed.

After the semiconductor process is evaluated, subsequent semiconductor processes are performed on the wafer W (operation S40). Subsequent semiconductor processes for the wafer W may include various processes. For example, the subsequent semiconductor process may include an oxidation process, a photo process, a deposition process, an etching process, an ion process, and/or a cleaning process. Also, the subsequent semiconductor processes may include a singulation process of individualizing the wafer W into individual semiconductor chips, a test process of testing the semiconductor chips, and a packaging process of packaging the semiconductor chips. A semiconductor device may be completed formed through the subsequent semiconductor processes for the wafer W.

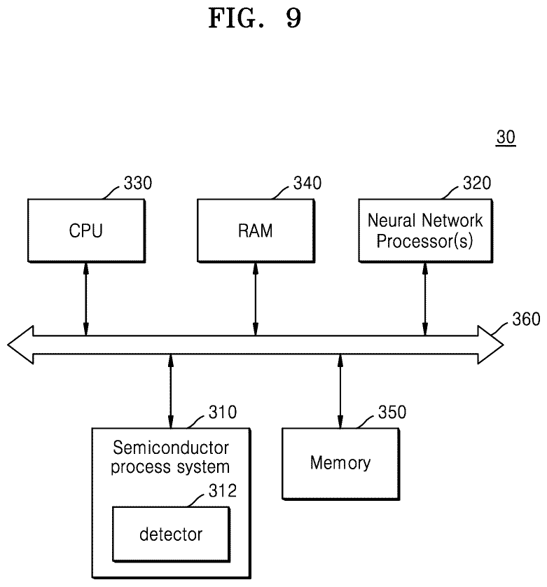

FIG. 9 is a block diagram showing an example of a semiconductor device manufacturing apparatus according to some implementations. Descriptions below will be given with reference to FIGS. 1 to 8, together.

In FIG. 9, a semiconductor device manufacturing apparatus 30 may generate an anomaly detection model for process variables using a neural network and determine whether there is an anomaly in time-series data. The semiconductor device manufacturing apparatus 30 may include a semiconductor process system 310, a neural network processor 320, a CPU 330, a random access memory (RAM) 340, a memory 350, and a bus 360.

In some implementations, the semiconductor device manufacturing apparatus 30 may further include other general-purpose components in addition to the components shown in FIG. 9. For example, the semiconductor device manufacturing apparatus 30 may further include an input/output module, a security module, a power control device, etc., and may further include various types of processors. Also, in some implementations, at least one of the components shown in FIG. 9 may be omitted from the semiconductor device manufacturing apparatus 30. Components of the semiconductor device manufacturing apparatus 30 may communicate with one another through the bus 360.

The semiconductor process system 310 may perform various processes on the wafer W. For example, the semiconductor process system 310 may perform an oxidation process, a photo process, a deposition process, an etching process, an ion process, and/or a cleaning process on the wafer W. The semiconductor process system 310 may detect variables of the semiconductor process through a detector 312, such that the neural network processor 320 may determine whether there is an anomaly in the semiconductor process performed by the semiconductor process system 310.

The neural network processor 320 may train (or learn) a neural network or infer information included in input data by analyzing the input data using a neural network. The neural network processor 320 may determine a situation or control components of an electronic device in which the neural network processor 320 is mounted, based on inferred information. Additionally, the neural network processor 320 may receive input data from the semiconductor process system 310 and pre-process the input data to generate data. The neural network processor 320 may perform a pre-processing operation on input data to improve the performance of the neural network processor 320. Pre-processing operations may include normalization of input data, performing noise reduction, and/or performing positional encoding on the input data.

The neural network processor 320 may receive input data. The neural network processor 320 may generate an anomaly detection model for pre-processed input data and calibrate the generated anomaly detection model. Also, the neural network processor 320 may classify the input data based on the anomaly detection model. The neural network processor 320 may be implemented by a neural network accelerator, a coprocessor, a digital signal processor (DSP), an application specific integrated circuit (ASIC), a field-programmable gate array (FPGA), a graphics processing unit (GPU), a Neural processing unit (NPU), a Tensor Processing Unit (TPU), and a Multi-Processor System-on-Chip (MPSoC).

The neural network processor 320 may be a neural network model based on at least one from among an Artificial Neural Network (ANN), a Convolution Neural Network (CNN), a Region with Convolution Neural Network (R-CNN), a Region Proposal Network (RPN), a Recurrent Neural Network (RNN), a Stacking-based Deep Neural Network (S-DNN), a State-Space Dynamic Neural Network (S-SDNN), a Deconvolution Network, a Deep Belief Network (DBN), a Restricted Boltzman Machine (RBM), a Fully Convolutional Network, a Long Short-Term Memory (LSTM) Network, a Classification Network, a Plain Residual Network, a Dense Network, a Hierarchical Pyramid Network, a Temporal Convolution Network, a Fully Convolutional Network, and a Transformer. Meanwhile, the types of neural network models are not limited to the above-stated examples.

The CPU 330 may control the overall operation of the semiconductor process system 310. The CPU 330 may include a single core or multi-cores. The CPU 330 may process or execute programs and/or data stored in a storage region, such as the memory 350, by using the RAM 340. For example, the CPU 330 may control the neural network processor 320 to execute an application and perform neural network-based tasks demanded as the application is executed.

The memory 350 may include at least one of a volatile memory and a non-volatile memory. The non-volatile memory includes a Read Only Memory (ROM), a Programmable ROM (PROM), an Electrically Programmable ROM (EPROM), an Electrically Erasable and Programmable ROM (EEPROM), and a flash memory. The volatile memory includes a dynamic RAM (DRAM), a static RAM (SRAM), a synchronous DRAM (SDRAM), a PRAM, an MRAM, an RRAM, an FeRAM, etc. According to some implementations, the memory 350 may include at least one of a hard disk drive (HDD), a solid state drive (SSD), a compact flash (CF) card, a secure digital (SD) card, a micro secure digital (Micro-SD) card, a mini Secure digital (Mini-SD) card, an extreme digital (xD) card, and a memory stick.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An anomaly detection method comprising:
receiving, using at least one computing device, data representing semiconductor process variables;
generating, using the at least one computing device, an anomaly detection model through a convolution algorithm and a transformer algorithm;
classifying, using the at least one computing device, the data by using the anomaly detection model to produce classified data; and
detecting, using the at least one computing device, based upon the classified data, an anomaly associated with the semiconductor process variables.

2. The anomaly detection method of claim 1, further comprising generating, using the at least one computing device, training data based on at least part of the received data,
wherein the training data is unlabeled data.

3. The anomaly detection method of claim 1, wherein the convolution algorithm is configured to transform a dimension of input data.

4. The anomaly detection method of claim 1, wherein the convolution algorithm comprises a temporal convolution network (TCN).

5. The anomaly detection method of claim 1, wherein the transformer algorithm comprises a transformer decoder algorithm.

6. The anomaly detection method of claim 1, wherein classifying the data includes:
classifying the data based on a probability distribution generated by the anomaly detection model and a loss function of actual data.

7. The anomaly detection method of claim 1, wherein the semiconductor process variables comprise at least one of a flow rate of a process gas with respect to time, a current, a voltage, a pressure, a wavelength of light, or an amount of light inside a chamber.

8. An anomaly detection method comprising:
receiving, using at least one computing device, time-series data representing semiconductor process parameters;
generating, using the at least one computing device, an anomaly detection model;
classifying, using the at least one computing device, the time-series data using the anomaly detection model to produce classified time-series data; and
detecting, using the at least one computing device, based upon the classified time-series data, an anomaly associated with the semiconductor process parameters,
wherein generating the anomaly detection model comprises:
performing pre-processing on the time-series data;
generating the anomaly detection model through a convolution algorithm and a transformer algorithm;
calculating a loss function of the anomaly detection model; and
calibrating the anomaly detection model.

9. The anomaly detection method of claim 8, further comprising classifying, using the at least one computing device, the time-series data into training time-series data and evaluation time-series data,
wherein the anomaly detection model is generated based on the training time-series data, and
wherein the evaluation time-series data is classified based on the generated anomaly detection model.

10. The anomaly detection method of claim 8,
wherein the loss function comprises cross entropy,
wherein classifying the time-series data includes:
classifying the time-series data as abnormal data based on the loss function being greater than a reference value, and,
classifying the time-series data as normal data based on the loss function being lower than the reference value.

11. The anomaly detection method of claim 8, wherein performing pre-processing on the time-series data includes:
performing positional encoding on the time-series data.

12. The anomaly detection method of claim 8, wherein performing the pre-processing on the time-series data comprises:
normalizing the time-series data; and
transforming the normalized time-series data into a one-hot vector representing data in a discrete manner.

13. The anomaly detection method of claim 8,
wherein the convolution algorithm comprises a temporal convolution algorithm, and
wherein the temporal convolution algorithm comprises a causal convolution algorithm and a dilation algorithm.

14. The anomaly detection method of claim 13, wherein, in the causal convolution algorithm, an output of each layer is output based on current data or preceding data in time series.

15. The anomaly detection method of claim 8, wherein the transformer algorithm comprises at least one of a masked multi-head attention algorithm, a multi-head attention algorithm, a feed-forward network (FFN) algorithm, or a linear projection algorithm.

16. The anomaly detection method of claim 15, wherein, in the masked multi-head attention algorithm, trailing values are masked at positions of input data in time series.

17. The anomaly detection method of claim 8, wherein the anomaly detection model is configured to generate a probability distribution of trailing data based on data that precedes input data in time series.

18. The anomaly detection method of claim 8, wherein the anomaly detection model is trained in an unsupervised training manner.

19. An anomaly detection method comprising:
receiving, using at least one computing device, time-series data representing semiconductor process parameters;
generating, using the at least one computing device, an anomaly detection model;
classifying, using the at least one computing device, the time-series data using the anomaly detection model to produce classified time-series data; and
detecting, using the at least one computing device, based upon the classified time-series data, an anomaly associated with the semiconductor process parameters,
wherein generating the anomaly detection model comprises:
performing pre-processing on the time-series data;
generating the anomaly detection model;
calculating a loss function of the anomaly detectin model; and
calibrating the anomaly detection model,
wherein generating the anomaly detectin model comprises:
performing a time convolution algorithm on the time-series data; and
performing a transformer decoder algorithm on the time-series data.

20. The anomaly detection method of claim 19, wherein the tranformer decoder algorithm is performed on the time-series data on which the temporal convolution algorithm has been performed.
